(19) United States
(12) Patent Application Publication
(10) Pub. No.: US 2025/0331278 A1
(43) Pub. Date: Oct. 23, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Yi-Ren Chen, Taoyuan City (TW); ChunTing Lee, Hsinchu County (TW); Shih-Hsun Chang, Hsinchu (TW); Jhon Jhy Liaw, Hsinchu County (TW)

(73) Assignee: Taiwan Semiconductor Manufacturing Company, Ltd., Hsinchu (TW)

(21) Appl. No.: 18/641,458

(22) Filed: Apr. 22, 2024

(51) Int. Cl. H01L 29/45; H01L 21/285; H01L 29/06; H01L 29/08; H01L 29/417; H01L 29/423; H01L 29/66; H01L 29/775

(52) U.S. Cl. CPC H10D 64/62; H01L 21/28518; H10D 30/014; H10D 30/43; H10D 30/6729; H10D 30/6735; H10D 62/121; H10D 62/151; H10D 64/018

(57) ABSTRACT

A semiconductor device includes a substrate, parallel channel members, a gate structure, a source and drain feature, a source and drain contact, a top spacer portion, and a lining structure. The parallel channel members are spaced apart and stacked in parallel to the substrate. The parallel channel members include an uppermost channel member farthest from the substrate. The gate structure is wrapping around the channel members. The source and drain feature is disposed besides the channel members and the gate structure. The source and drain contact is disposed on the source and drain feature and besides the gate structure. The top spacer portion is disposed beside the gate structure, disposed on and in contact with the uppermost channel member. The lining structure is interposed between the source and drain contact and the top spacer portion. A bottom of the lining structure is located above the uppermost channel member.

### BACKGROUND

The semiconductor integrated circuit (IC) industry has experienced exponential growth. Technological advances in IC materials and design have produced generations of ICs where each generation has smaller and more complex circuits than the previous generation, therefore, semiconductor structures need to be improved.

### BRIEF DESCRIPTION OF THE DRAWINGS

FIGS. 1-13 illustrate schematic cross-sectional views of a semiconductor device during various stages of a fabrication process according to some embodiments of the present disclosure.

FIG. 14 is a schematic layout showing the relative positions of contact in the semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

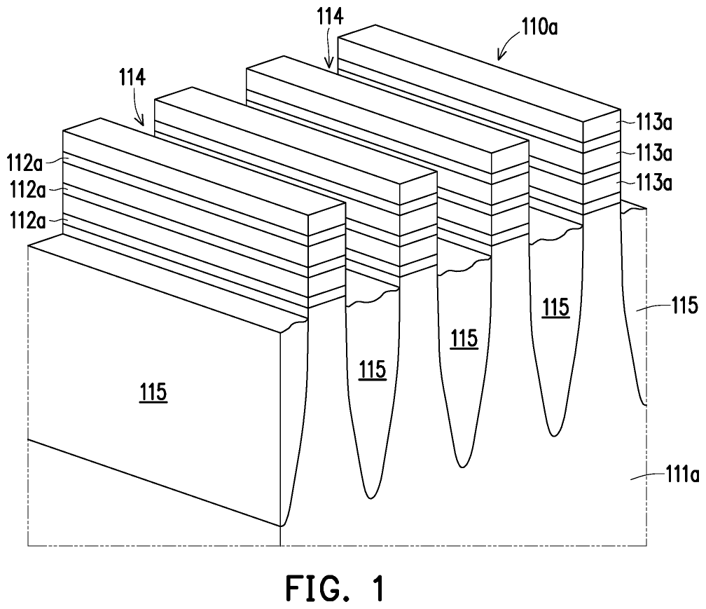

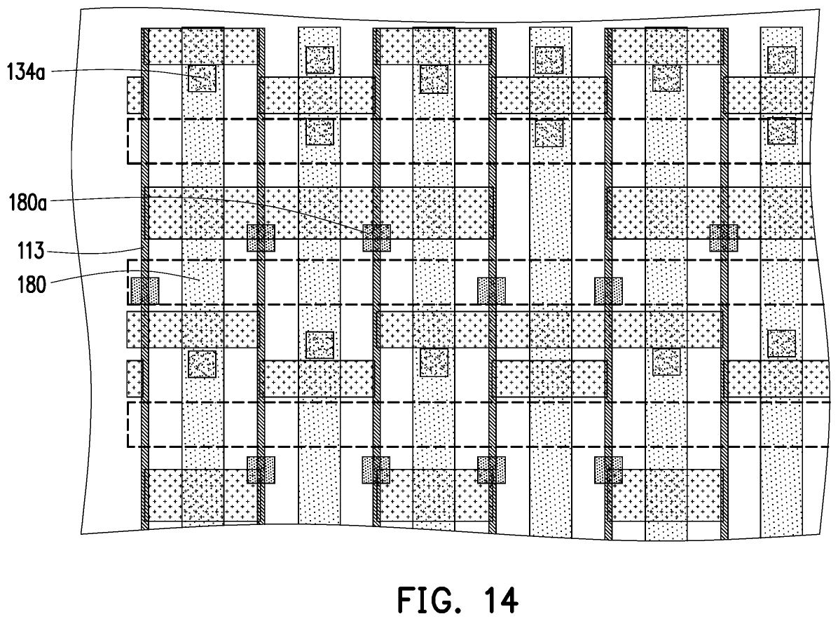

FIGS. 1-13 illustrate schematic cross-sectional views of a semiconductor device during various stages of a fabrication process according to some embodiments of the present disclosure. FIG. 14 is a schematic layout showing the relative positions of contact in the semiconductor device in accordance with some embodiments of the present disclosure.

Referring to FIG. 1, vertical stacks 110a are formed on a provided substrate 111a. In some embodiments, each of the vertical stacks 110a includes stacked patterned semiconductor layers on the provided substrate 111a. The stacked patterned semiconductor layers may include first patterned semiconductor layers 112a and second patterned semiconductor layers 113a stacked in alternation. Herein, the second patterned semiconductor layers 113a may be served as channel members in semiconductor device.

In some embodiments, the provided substrate 111a is or includes a semiconductor substrate such as a silicon substrate, a silicon-on-insulator (SOI) substrate, a silicon-germanium on insulator (SGOI) or a germanium-on-insulator (GOI) substrate. In some embodiments, the provided substrate 111a is provided in a wafer form, and is or includes a semiconductor wafer such as a silicon bulk wafer or SOI wafer. Further, the provided substrate 111a may include various doping configurations depending on design requirements. In some embodiments, different doping profiles (e.g., n-wells, p-wells) are formed in the provided substrate 111a in regions designed for different device types (e.g., n-type devices and p-type devices). The suitable doping may include ion implantation of dopants and/or diffusion processes.

In some embodiments, the first patterned semiconductor layers 112a include silicon germanium (SiGe) and the second patterned semiconductor layers 113a include silicon (Si). Alternatively, in some embodiments, either of the first patterned semiconductor layers 112a and the second patterned semiconductor layers 113a include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof.

In some embodiments, the first patterned semiconductor layers 112a and the second patterned semiconductor layers 113a are formed by epitaxial growth processes such as molecular beam epitaxy (MBE) processes, metalorganic chemical vapor deposition (MOCVD) processes, and/or other suitable epitaxial growth processes. It should be noted that a number of aforementioned layers which is for illustrative purposes only and not intended to be limiting beyond what is specifically recited in the claims. It can be appreciated that any number of semiconductor layers may be formed, and the number of layers depends on the desired number of channels for the semiconductor device.

In some embodiments, the first patterned semiconductor layers 112a and the second patterned semiconductor layers 113a are formed by patterning the alternately arranged multiple first semiconductor layers and multiple second semiconductor layers (not shown) deposited over the bulk substrate (not shown). For example, a plurality of trenches 114 may be formed in the alternately stacked first semiconductor layers and second semiconductor layers by partial removing the first and second semiconductor layers by using a lithography process and an etch process with a hard mask layer (not shown), such that the first patterned semiconductor layers 112a and the second patterned semiconductor layers 113a are formed.

In some embodiments, the lithography process includes photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process includes dry etching (e.g., RIE etching), wet etching, and/or other etching methods.

In FIG. 1, isolation structures 115 are formed in the trenches 114. The isolation structures 115 include shallow trench isolation (STI) structures. In some embodiments, the formation of STI structures involves depositing a dielectric layer (not shown) into the trenches 114 over the provided substrate 111a, and then a planarization process, an etching process (or a pulled-back process) may be performed to the dielectric layer to form the isolation structures 115. In some embodiments, the material of the isolation structures 115 includes silicon oxide, silicon nitride, silicon oxynitride, fluorine-doped silicate glass (FSG), a low-k dielectric, combinations thereof, and/or other suitable materials. In some embodiments, the planarization process includes performing a chemical mechanical polishing (CMP) process. In some embodiments, the etching process includes performing a dry etching process, a wet etching process, and/or a combination thereof.

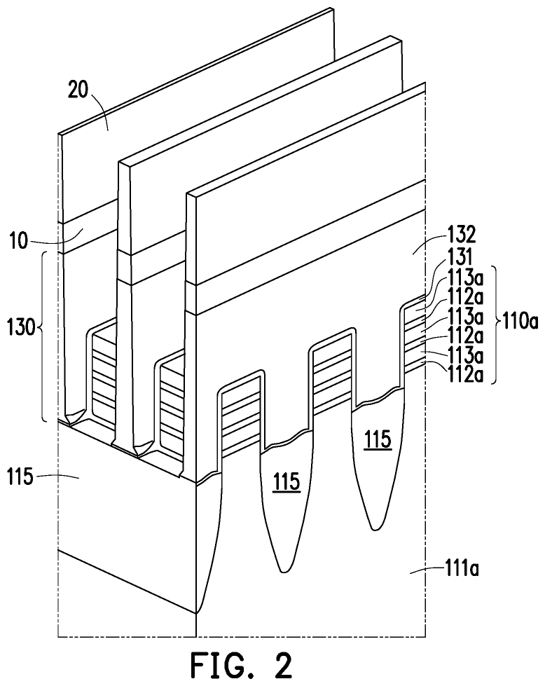

Referring to FIG. 2, dummy gate structures 130 are formed over and across the vertical stacks 110a, wrapping around the first patterned semiconductor layers 112a and the second patterned semiconductor layers 113a. In some embodiments, each of the dummy gate structures 130 includes a dummy dielectric layer 131 and a dummy gate 132 formed across the vertical stacks 110a and on the isolation structures 115. In some embodiments, the dummy dielectric material and the dummy gate material (not shown) are formed over the vertical stacks 110a and the provided substrate 111a as blanket layers, and then patterned with a mask pattern of a first hard mask layer 10 and a second hard mask layer 20 to form the dummy gate structures 130.

In some embodiments, the dielectric material of the dummy dielectric layer 131 includes silicon oxide, silicon nitride, a high-K dielectric material and/or other suitable material. In various examples, the dummy dielectric layer 131 is deposited by a CVD process, a sub-atmospheric CVD (SACVD) process, a flowable CVD process, an ALD process, a PVD process, or other suitable process.

In some embodiments, the material of the dummy gate 132 includes polysilicon and/or other suitable semiconductor material. In various examples, the dummy gate 132 is deposited by a CVD process, a sub-atmospheric CVD (SACVD) process, a flowable CVD process, an ALD process, a PVD process, or other suitable process.

In some embodiments, the first hard mask layer 10 is formed of silicon oxide and the second hard mask layer 20 is formed of silicon nitride. The first hard mask layer 10 and the second hard mask layer 20 may be formed using chemical vapor deposition (CVD), low-pressure CVD (LPCVD), plasma-enhanced CVD (PECVD), physical vapor deposition (PVD), atomic layer deposition (ALD), thermal oxidation, electron-beam (e-beam) evaporation, or other suitable deposition techniques, or combinations thereof.

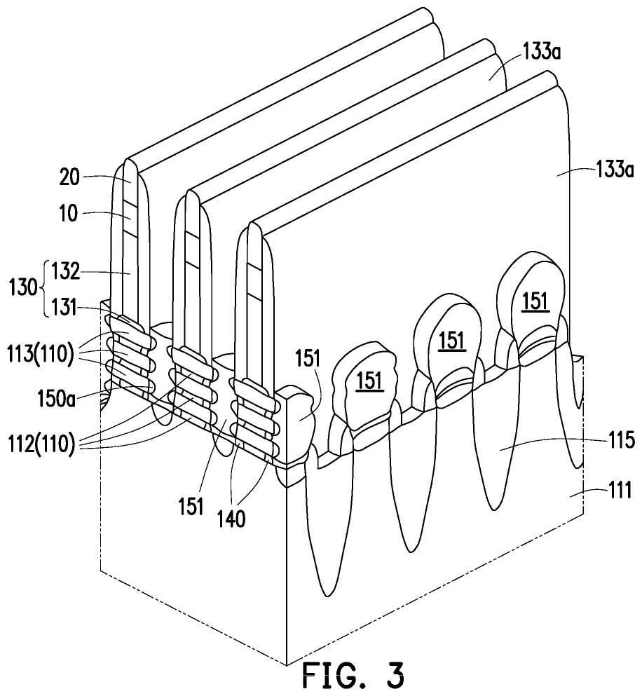

Referring to FIG. 3, in some embodiments, gate spacers 133a are formed on sidewalls of the dummy gate structures 130. In some embodiments, the gate spacers 133a are formed by conformally depositing a gate spacer material layer (not shown) over the provided substrate 111a, wherein the term “conformally” may be used herein for ease of description of a layer having substantially uniform thickness over various regions, therefore, the dummy gate structures 130, the first hard mask layer 10, and the second hard mask layer 20 are fully covered by the gate spacer material layer, and the gate spacer material layer is etched back in an anisotropic etch process to formed the gate spacers 133a.

In some embodiments, the materials of the gate spacers 133a include silicon carbonitride, silicon oxycarbide, silicon oxycarbonitride, or silicon nitride, or a combination thereof, and the gate spacers 133a are formed using on or more CVD processes such as, a sub-atmospheric CVD (SACVD) process, a flowable CVD process, an ALD process, or a PVD process, or other suitable processes.

Referring to FIG. 3, after the gate spacers 133a are formed, the vertical stacks 110a and the provided substrate 111a are etched to form etched vertical stacks 110 and substrate 111, and spacer features 140 and source and drain features 151 are then formed. Herein, the etched vertical stacks 110 includes sacrificial layers 112 (etched first patterned semiconductor layers 112a) and channel layers 113 (etched second patterned semiconductor layers 113a). Further, the gate spacers 133a and the spacer features 140 may be considered as a spacer portion.

Referring to FIG. 3, the spacer features 140 are formed in the sacrificial layers 112 of the vertical stacks 110. In FIG. 3, in some embodiments, the source and drain features 151 are formed on the etched vertical stacks 110 over the substrate 111 and are formed to cover the sacrificial layers 112 and the channel layers 113. Further, the source and drain features 151 are located at opposite sides of the dummy gate structures 130 beside the opposing gate spacers 133a on the dummy gate structures 130.

For example, source and drain recesses and spacer recesses (not shown) may be formed by a suitable etching process with the gate spacers 133a. In some embodiments, the sacrificial layers 112 exposed in the source and drain recesses are selectively and partially further recessed to form the spacer recesses while the gate spacers 133a and the channel layers 113 are substantially unetched. In some embodiments, the selective recess is a selective isotropic etching process (e.g., a selective dry etching process or a selective wet etching process), and the extent the sacrificial layers 112 are recessed is controlled by duration of the etching process.

After the source and drain recesses and the spacer recesses are formed, an spacer material layer (not shown) is formed over the substrate 111, and etch-back of the spacer material layer to form the spacer features 140. In some implementations, the spacer material layer may include ILD material such as metal oxides, silicon oxide, silicon oxycarbonitride, silicon nitride, silicon oxynitride, carbon-rich silicon carbonitride, or a low-k dielectric material. The metal oxides here may include aluminum oxide, zirconium oxide, tantalum oxide, yttrium oxide, titanium oxide, lanthanum oxide, or other suitable metal oxide and may be deposited using CVD, PECVD, LPCVD, ALD or other suitable method.

In some embodiments, the material of the source and drain features 151 includes suitable epitaxial processes include CVD deposition techniques (e.g., vapor-phase epitaxy (VPE) and/or ultra-high vacuum CVD (UHV-CVD)), molecular beam epitaxy (MBE), and/or other suitable processes may be used to form the source and drain features 151 in the source and drain recesses.

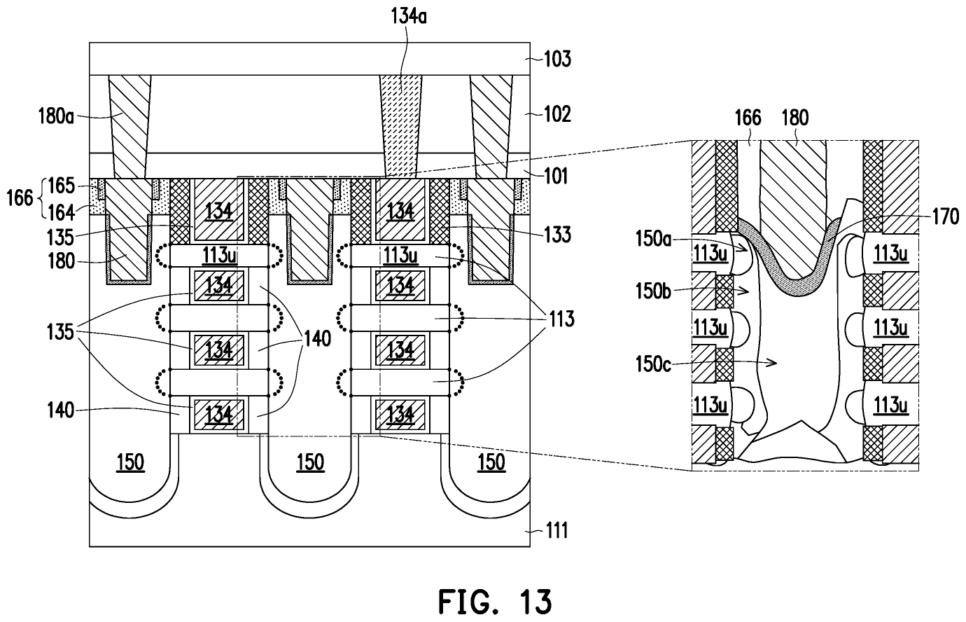

In FIG. 3, the source and drain features 151 may have a first doping concentration areas 150a formed on outer surfaces of the channel layers 113. In some embodiments, the first doping concentration areas 150a are formed by a selective growth process where a semiconductor material is grown on selective surfaces. An epitaxial profile of the source and drain features may be described in detail as below (see FIG. 13).

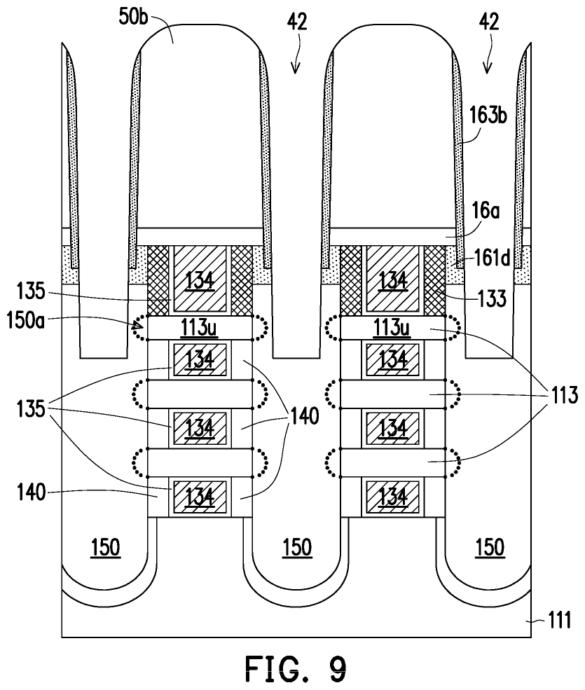

In FIG. 3, the source and drain features 151 are located beside and cover the spacer features 140 and the channel layers 113. For example, top surfaces of the source and drain features 151 are higher than the uppermost channel layer 113u of the channel layers 113 (as shown in FIG. 9).

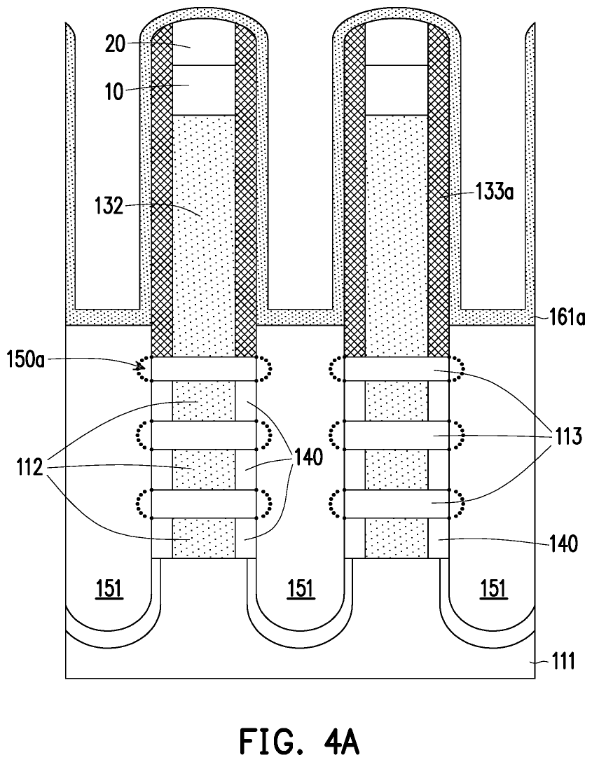

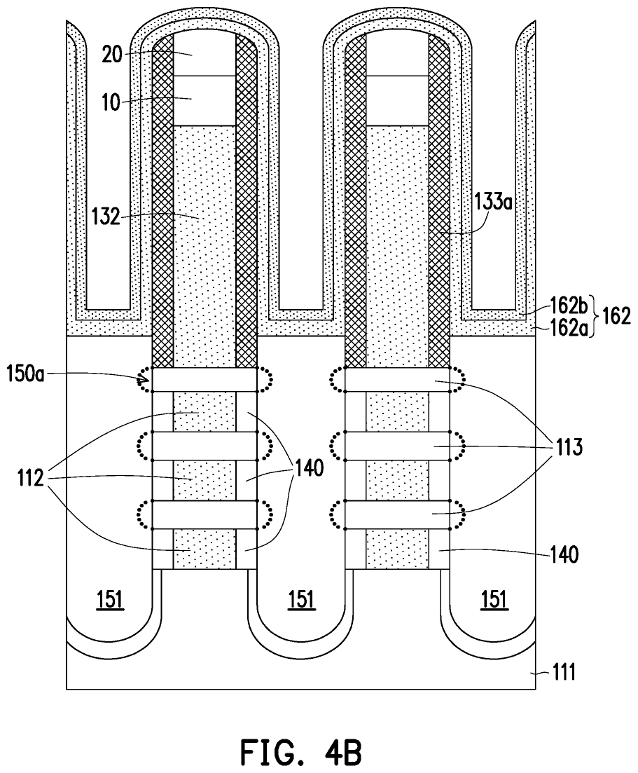

Referring to FIG. 4A, an etching stop layer 161a with a dielectric material may be formed conformally over the substrate 111 to protect underlying components. In some embodiments, the etching stop layer 161a is formed by ALD, plasma-enhanced chemical vapor deposition (PECVD) process and/or other suitable deposition or oxidation processes. In some embodiments, the etching stop layer 161a is or includes a single layer of a nitride material, such as a silicon nitride, silicon oxynitride, silicon carbonitride or the like. The etching stop layer 161a covering top surfaces of the source and drain features 151, for example, the etching stop layer 161a is in direct contact with the top surfaces of the source and drain features 151.

Alternatively, in other embodiments, the etching stop layer is a multi-layered structure. As shown in FIG. 4B, the etch stop layer 162 is a composite layer of an inner etching stop layer 162a and an outer etching stop layer 162b. In some examples, the inner etching stop layer 162a and the outer etching stop layer 162b are made of different dielectric materials. For example, the inner etching stop layer 162a may be formed of a low-k dielectric material (the dielectric constants (k values) of the low-k dielectric material lower than about 3.0). In some embodiments, the inner etching stop layer 162a includes a carbon-containing low-k dielectric material, hydrogen silsesQuioxane (HSQ), methylsilsesquioxane (MSQ), or the like. In some embodiments, the outer etching stop layer 162b is made of a nitride material, such as a silicon nitride, silicon oxynitride, silicon carbonitride or the like. The outer etching stop layer 162b has a hardness larger (i.e. harder) that of the inner etching stop layer 162a, while the inner etching stop layer 162a has a dielectric constant lower than that of the outer etching stop layer 162b.

In some embodiments, a thickness of the etching stop layers 161a, 162 may be thick enough to protect the underlying components from an etchant of the subsequent process. In some embodiments, the etching stop layers 161a, 162 functions as an etching stop layer for forming contact openings of source and drain, and the etching stop layers 161a, 162 are formed with a thickness thick enough so that the etching stop layers 161a, 162 will not be etched through during first contact openings formation. For example, a thickness of the etching stop layers 161a, 162 ranges from 2 nm to 6 nm. In some embodiments of FIG. 4B, the inner etching stop layer 162a ranges from 1 nm to 4 nm. In some embodiments, the outer etching stop layer 162b ranges from 2 nm to 5 nm.

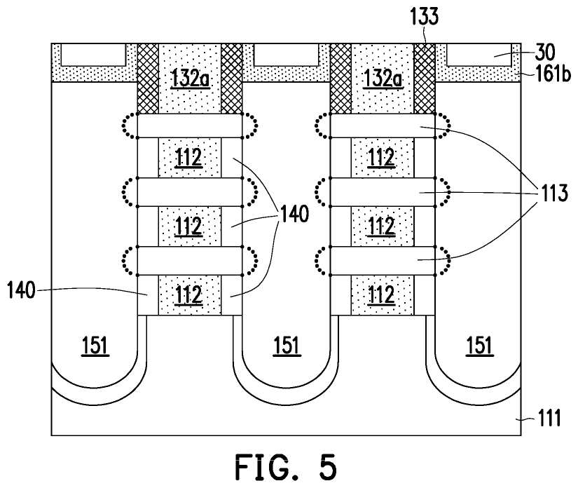

Referring to FIG. 5, following the formation of the etching stop layer 161a as described in FIG. 4A, an interlayer dielectric (ILD) layer 30 is formed, for example, the interlayer dielectric material (not shown) is deposited over the etching stop layer 161a, covering the etching stop layer 161a and then the interlayer dielectric material, the etching stop layer 161a, the gate spacers 133a, and dummy gate 132 are planarized simultaneously to form the interlayer dielectric layer 30, a first remained etching stop layer 161b, a remained gate spacers 133, and a remained dummy gate 132a, as shown in FIG. 5. For example, the planarization process may include a chemical mechanical planarization (CMP) process.

In some examples, the interlayer dielectric layer 30 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The interlayer dielectric layer 30 is deposited by a PECVD process or other suitable deposition technique.

Following by FIG. 5, removing the dummy gate structures 130, for example, the remained dummy gate 132a and the dummy dielectric layer 131 may be removed (for clear illustration, the dummy dielectric layer 131 is not shown in FIG. 4A, FIG. 4B, and FIG. 5). The removal of the remained dummy gate 132a and the dummy dielectric layer 131 may include one or more etching processes that are selective to the material in the remained dummy gate 132a and the dummy dielectric layer 131.

After the removal of the remained dummy gate 132a and the dummy dielectric layer 131, the method may include operations to selectively remove the sacrificial layers 112 between the channel layers 113. The selective removal of the sacrificial layers 112 releases the channel layers 113, such that the channel layers 113 are spaced apart and stacked in parallel to the substrate 111.

The selective removal of the sacrificial layers 112 may be implemented by selective dry etch, selective wet etch, or other selective etch processes. In some embodiments, the selective wet etching includes an APM etch (e.g., ammonia hydroxide-hydrogen peroxide-water mixture). In some embodiments, the selective removal includes SiGe oxidation followed by a SiGeOx removal. For example, the oxidation may be provided by ozone clean and then SiGeOx removed by an etchant such as NH4OH.

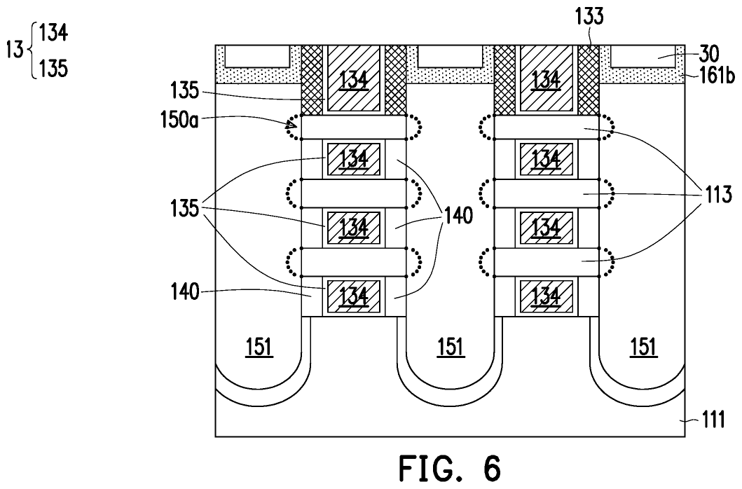

Referring to FIG. 6, after removing the dummy gate structures 130 and the sacrificial layers 112, a gate structures 13 wrapping the channel layers 113 are formed, wherein the gate structures 13 may be a high-K metal gate structure.

In some embodiments, the gate structures 13 may include a metal, metal alloy, or metal silicide, for example, the gate electrode layer 134 of the gate structures 13 includes Ti, Ag, Al, TiAIN, TaC, TaCN, TaSiN, Mn, Zr, TiN, TaN, Ru, Mo, Al, WN, Cu, W, Re, Ir, Co, Ni, other suitable metal materials or a combination thereof. The dielectric layers 135 Of gate structures 13 includes dielectric materials having a high dielectric constant, for example, greater than that of thermal silicon oxide. In some embodiments, the gate electrode layers 134 is formed by ALD, PVD, CVD, e-beam evaporation, or other suitable process, and the dielectric layers 135 is formed by ALD, physical vapor deposition (PVD), CVD, oxidation, and/or other suitable methods.

In various embodiments, a CMP process may be performed to remove excessive metal from the gate structures 134, and thereby provide a substantially planar top surface of the gate structure 13, the interlayer dielectric layer 30 and the first remained etching stop layer 161b. In here, a plurality of gate-all-around (GAA) transistors are formed on the substrate 111, and each of the GAA transistor may include the channel layers 113 (channel members) and the gate structure 13. Further, the source and drain features 151 are disposed on the substrate 111 and between the two GAA transistors. It should be note that, the aforementioned structure and process can also be applied to CMOS forksheet structures, CMOS nanosheet structures.

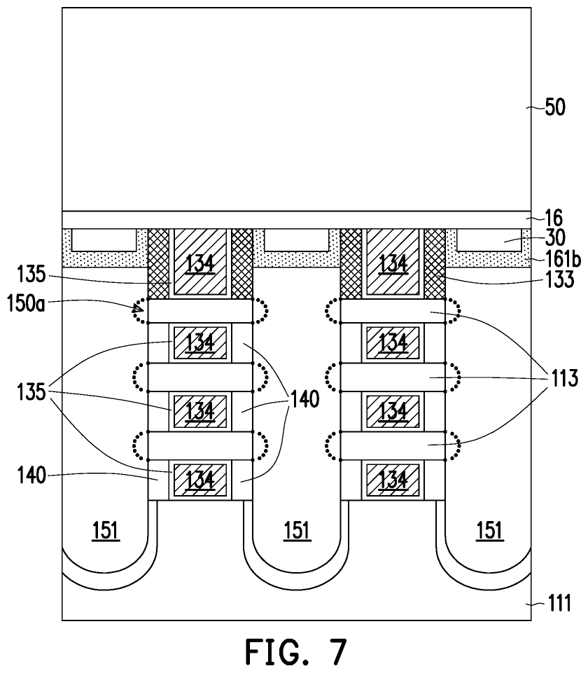

Referring to FIG. 7, an etching stop material layer 16 and an interlayer dielectric (ILD) material layer 50 are conformally formed on the substrate 111. In some embodiments, the etching stop material layer 16 is formed by ALD, plasma-enhanced chemical vapor deposition (PECVD) process and/or other suitable deposition or oxidation processes. In the embodiment, the etching stop material layer 16 is a single layer (such as a silicon nitride layer or the like). In some embodiments, the interlayer dielectric material layer 50 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The interlayer dielectric material layer 50 is deposited by a PECVD process or other suitable deposition technique.

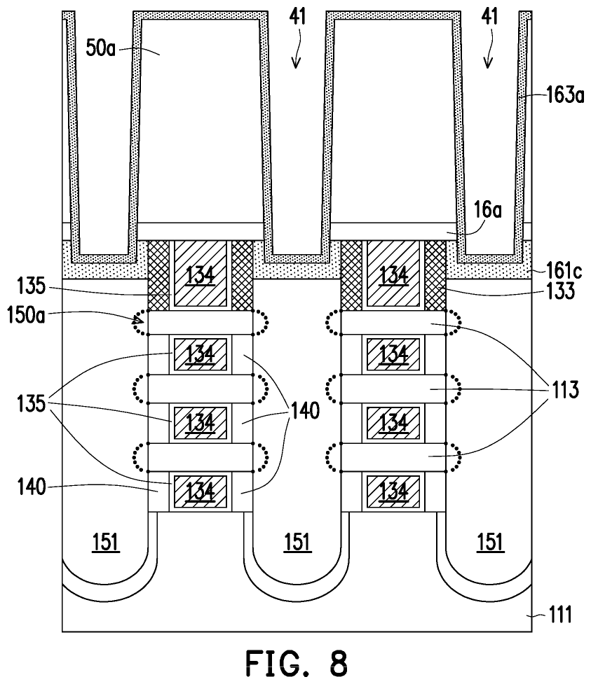

Referring to FIG. 8, source and drain contact openings 41 are formed by performing an etching process to penetrate through the interlayer dielectric material layer 50, the etching stop material layer 16 and the first remained etching stop layer 161b to form the interlayer dielectric layer 50a, an etching stop layer 16a and a second remained etching stop layer 161c, but stopping at (not penetrating through) the second remained etching stop layer 161c. Further, the source and drain contact openings 41 may expose a top surface of the second remained etching stop layer 161c.

Due to the existence of the thicker etching stop layer 161a (as shown in FIG. 4A), the source and drain features 151 below the etching stop layer 161a is protected and undamaged. In these embodiments, after forming the source and drain contact openings 41, the first remained etching stop layer 161b is not etched or partially etched through and remained on the source and drain features 151, therefore, the source and drain features 151 may not be damaged, thereby the source and drain features 151 have better quality to allow current to pass thereof as follow.

For example, the etching process includes a dry etching process, a wet etching process, a RIE process, other suitable methods, or combinations thereof. A dry etching process may use chlorine-containing gases, fluorine-containing gases, and/or other etching gases. Wet etching solutions may include ammonium hydroxide (NH₄OH), hydrofluoric acid (HF) or diluted HF, deionized water, tetramethylammonium hydroxide (TMAH), and/or other suitable wet etching solutions. In some embodiments, the etching process includes multiple etching steps with different etching chemistries, designed for etching selectivity to form features having a desired profile.

Referring to FIG. 8, a dielectric material layer 163a is formed over the substrate 111 conformally covering sidewalls and bottom surfaces of the contact openings 41. In these embodiments, the dielectric material layer 163a is not formed deeper than the first remained etching stop layer 161b.

Later, referring to FIG. 9, an etching process is performed to form contact openings 42 inside the contact openings 41. In some embodiments, the etching process etches the ILD layer 50a into a rounded ILD layer 50b, etches the second remained etching stop layer 161c into the third remained etching stop layer 161d, etches the dielectric layer 163a into the liner dielectric layer 163b and etches the source and drain features 151 into the etched source and drain features 150.

In some embodiments, the contact openings 42 extend into the source and drain features 151 with a depth, and the bottoms of the contact openings 42 may be lower than as the top surfaces of the etched source and drain features 150 higher than the uppermost channel layers 113u. The third remained etching stop layer 161d is located on the top surfaces of the etched source and drain features 150 and higher than the uppermost channel layers 113u. In these embodiments, the liner dielectric layer 163b is separated from the etched source and drain features 150 by the third remained etching stop layer 161d.

In some embodiments, the third remained etching stop layer 161d, the liner dielectric layer 163b are located over the uppermost channel layers 113u farthest from the substrate 111. Further, the liner dielectric layer 163b may be not formed beside an uppermost channel layers 113u, such that a bottom surface of the uppermost channel layers 113u is disposed over a top surface of the etched source and drain features 150.

Alternatively, in not illustrated embodiments, the etching stop layer may further extend to beside a top surface of the uppermost channel layers, such that a bottom surface of the etching stop layer is substantially coplanar with the top surface of the uppermost channel layers, or a bottom surface of the etching stop layer is slightly higher than the top surface of the uppermost channel layers.

In some embodiments, the liner dielectric layer 163b is surrounded by the third remained etching stop layer 161d after the formation of the second contact openings 42, for example, the third remained etching stop layer 161d is interposed between the gate structures 13 and the liner dielectric layer 163b.

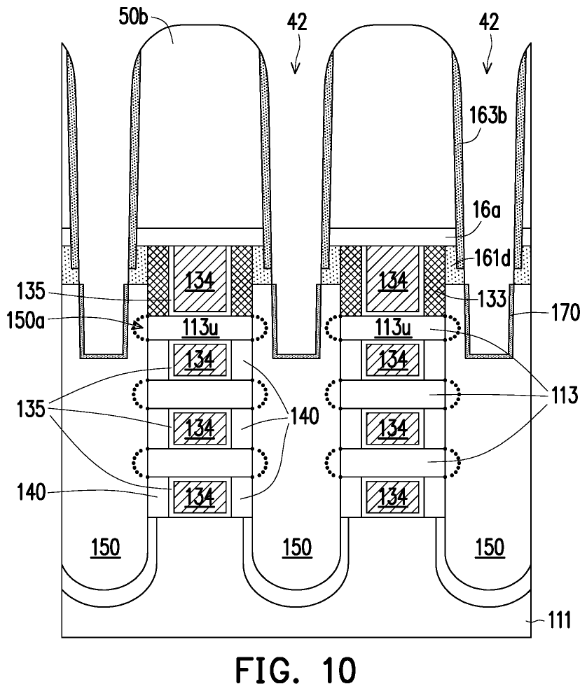

Referring to FIG. 10, following the process of FIG. 9, a silicide layer 170 is deposited over the substrate 111. In some embodiments, the formation of the silicide layer 170 involves depositing a metal material (not shown) over the substrate 111 and performing a heating process to allow the metal to be reacted with the underlying silicon to form the silicide. In some embodiments, the metal material is conformally covering the profiles of the etched source and drain features 150 in the contact openings 42.

In some embodiments, the metal material includes cobalt (Co), titanium (Ti), nickel (Ni), molybdenum (Mo), ruthenium (Ru), or alloys thereof. In some embodiments, during the heating process, the metal from the metal material is reacted with underlying semiconductor material (e.g. silicon) of etched source and drain features 150. In some embodiments, the material of the silicide layer 170 includes NiSi, TiNiSi, CoSi, MoSi, RuSi, TiSi, or combinations thereof.

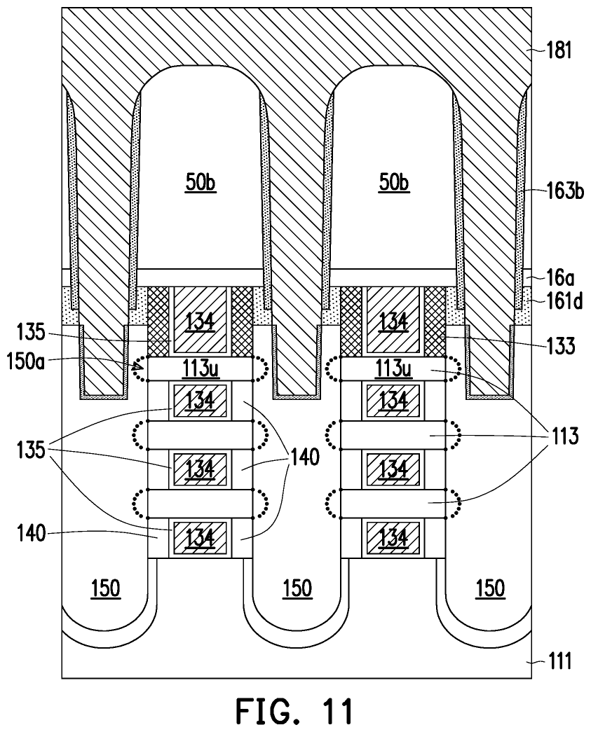

Referring to FIG. 11, a metal material 181 is conformally deposited over the substrate 111 and filling into the contact openings 42. In some embodiments, the metal material 181 includes Co, Mo, Cu, Ru, W, or combinations thereof, and formed by ALD, PVD, CVD, e-beam evaporation, plating or other suitable process.

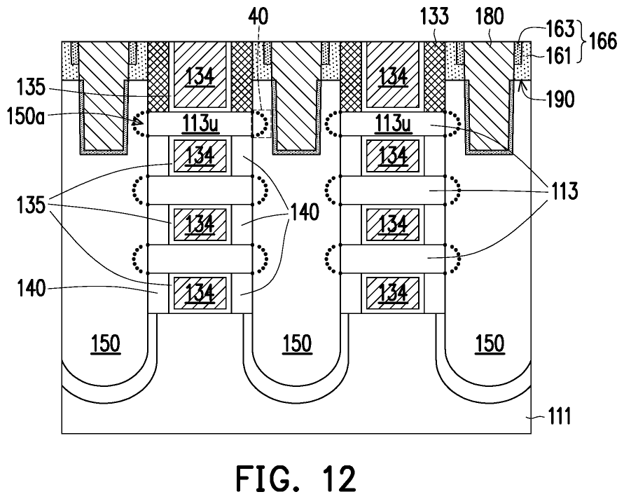

Referring to FIG. 12, a planarization process (such as CMP process) may be performed to remove excessive metal material 181, the third remained etching stop layer 161d, the etching stop layer 16a, the rounded interlayer dielectric layer 50b and the liner dielectric layer 163b, such that source and drain contacts 180, a fourth remained etching stop layer 161 and a remained dielectric layer 163 are formed, and thereby provide a substantially planar top surface of the source and drain contacts 180, a fourth remained etching stop layer 161 and a remained dielectric layer 163. In here, the fourth remained etching stop layer 161 and the remained dielectric layer 163 may function as a lining structure 166. Moreover, a contact surface 109 of the lining structure 166 and the source and drain features 150 is located above the uppermost channel layers 113u.

In some embodiments, the source and drain contacts 180 are disposed besides the channel layers 113 and extended into the etched source and drain features 150, for example, the source and drain contacts 180 are surrounded by the etched source and drain features 150. In some embodiments, the remained gate spacers 133 (top spacer portion) is disposed on and in direct contact with the uppermost channel layers 113u, and the gate structures 134 include a top gate disposed over the uppermost channel layers 113u.

In FIG. 12, the lining structure 166 is interposed between the source and drain contact 180 and the remained gate spacers 133, and a bottom end of the lining structure 166 is located above the uppermost channel layers 113u. Moreover, as the bottom end of the lining structure 166 is located above the uppermost channel layers 113u and the silicide layer 170 is adjacent to the top gate, currents may flow directly from the uppermost channel layers 113u through the semiconductor zone in the source and drain features 150 to the source/drain contacts 180. As there is no dielectric lining structure located in-between the current flowing path between the uppermost channel layers 113 and the source and drain contacts 180, current crowding effect is minimized. By doing so, the electrical performance of the device is improved and the resultant contacts have lower contact resistance.

For example, in CMOS processes, as dimensions of the semiconductor device are small, during the formation of the source and drain contact openings, epitaxy materials in the source and drain features may easily be damaged, leading to high contact resistance for the source and drain contacts. Through the formation of thicker etching stop layer as described in this disclosure, the epitaxy materials in the source and drain features are protected. Also, the formation of a compact lining structure 166 that does not extend beyond the uppermost channel layers avoids undesirable current crowding effects and improves device performance. Moreover, as the remained dielectric layer 163 surrounding the source and drain contacts 180 is relatively thin, a larger landing window is offered for later formed contact vias that are landed on the source and drain contacts.

For the source and drain features 150 made of epitaxy semiconductor materials, the source and drain features 150 comprise a semiconductor zone 40, the semiconductor zone 40 only containing semiconductor material(s) without any dielectric material, between the silicide layer 170 and the channel layers 113, as the lining structure 166 is controlled not to extend below the uppermost channel layers 113u and not to cover the uppermost channel layers 113u. Hence, the semiconductor zone 40 between the uppermost channel layers 113u and the source and drain contacts 180 is a dielectric-free zone. In these embodiments, the current can flow through the semiconductor zone without obstruction.

In some embodiments, the silicide layer 170 and the lining structure 166 are intersected beside the remained gate spacers 133 and contacted to each other and a portion of the source and drain features 150 is confined by the silicide layer 170 and the lining structure 166. In some embodiments, sidewalls of the remained gate spacers 133 are partial covered by the lining structure 166 and sidewalls of the uppermost channel layers 113 are not covered by the lining structure 166. In not shown embodiments, the sidewalls of the remained gate spacers 133 are fully covered by the lining structure 166 and sidewalls of the uppermost channel layers 113u are not covered by the lining structure 166.

In some embodiments, a bottom surface of the lining structure 166 is higher than a bottom surface of the remained gate spacers 133 in a vertical direction. As the lining structure 166 is tuned to be located above the uppermost channel layers 113u, there is no dielectric material (no dielectric lining structure 166) present in the zone between the uppermost channel layers 113u and the source and drain contacts 180. Such dielectric-free zone is beneficial for lowering the contact resistance of the later-formed contacts. In some embodiments, the top end of the silicide layer 170 is located above a top surface of the uppermost channel layers 113u and zone is located between the silicide layer 170 and the uppermost channel layers 113u.

Referring to FIG. 13 and FIG. 14, an etching stop material layer 101 and an interlayer dielectric material layer 102 are conformally formed on the substrate 111. In some embodiments, the etching stop material layer 101 is formed by ALD, plasma-enhanced chemical vapor deposition (PECVD) process and/or other suitable deposition or oxidation processes. In the embodiment, the etching stop material layer 101 is a single layer (such as a silicon nitride layer or the like). In some embodiments, the interlayer dielectric material layer 102 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The interlayer dielectric material layer 102 is deposited by a PECVD process or other suitable deposition technique.

And then, source and drain contact vias 180a are penetrated through the etching stop material layer 101 and the interlayer dielectric material layer 102 and electrically contacted to the source and drain contacts 180. Further, gate contact vias 134a are penetrated through the etching stop material layer 101 and the interlayer dielectric material layer 102 and electrically contacted to the gate structure 13.

In some embodiments, the source and drain contact vias 180a and the gate contact vias 134a include Co, Mo, Cu, Ru, W, or combinations thereof, and formed by ALD, PVD, CVD, e-beam evaporation, plating or other suitable process.

A planarization process (such as CMP process) may be performed to remove excessive the source and drain contact vias 180a, the gate contact vias 134a and the interlayer dielectric material layer 102. An interconnect 103 then are conformally formed on the substrate 111 and the semiconductor device 100 is almost complete. The interconnect 103 includes conductive contacts, interconnects wires, and/or interconnect vias, and formed by ALD, PVD, CVD, e-beam evaporation, plating or other suitable process.

In some embodiments, the source and drain features 150 comprises a second doping concentration area 150b and a third doping concentration area 150c, and the second doping concentration area 150b is interposed between the first doping concentration area 150a and the third doping concentration area 150c. Moreover, the first doping concentration area 150a is located between the uppermost channel layers 113u and the second doping concentration area 150b, the lining structure 166 is separated from the first doping concentration area 150a. In here, a doping concentration of the second doping concentration area 150b is greater than a doping concentration of the first doping concentration area 150a and a doping concentration of the third doping concentration area 150c is similar to the doping concentration of the second doping concentration area 150b.

In some embodiments, a dopant of the first doping concentration area 150a includes germanium (Ge), phosphorus (P), Boron (B), Arsenic (As), or the like, a dopant of the second doping concentration area 150b includes germanium, phosphorus, Boron (B), Arsenic (As), or the like, and a dopant of the third doping concentration area 150c includes germanium, phosphorus, Boron (B), Arsenic (As), or the like.

In some embodiments, the doping concentration of germanium of the first doping concentration area 150a ranges from 0% to 10%, the doping concentration of germanium of the second doping concentration area 150b ranges from 11% to 30%, the doping concentration of germanium of the third doping concentration area 150c ranges from 40% to 60%. In some embodiments, the doping concentration of phosphorus of the first doping concentration area 150a ranges from 10²⁰ (1E20) to 2*10²¹ (2E21), the doping concentration of phosphorus of the second doping concentration area 150b ranges from 10²¹ (1E21) to 2*10²¹ (2E21), the doping concentration of phosphorus of the third doping concentration area 150c ranges from 2*10²¹ (2E21) to 10²² (1E22).

In accordance with some embodiments of the present disclosure, a semiconductor device includes a substrate, parallel channel members, a gate structure, a source and drain feature, a source and drain contact, a top spacer portion, and a lining structure. The parallel channel members are spaced apart and stacked in parallel to the substrate. The parallel channel members include an uppermost channel member farthest from the substrate. The gate structure is wrapping around the channel members. The source and drain feature is disposed besides the channel members and the gate structure. The source and drain contact is disposed on the source and drain feature and besides the gate structure. The top spacer portion is disposed beside the gate structure, disposed on and in contact with the uppermost channel member. The lining structure is interposed between the source and drain contact and the top spacer portion. A bottom of the lining structure is located above the uppermost channel member.

In accordance with some embodiments of the present disclosure, a semiconductor device includes channel members, a gate structure, a source and drain feature, a source and drain contact, a silicide layer, and a lining structure. The channel members are spaced apart from one another. The channel members comprise a first channel member and a second channel member disposed above the first channel member. The gate structure is wrapping around the channel members. The gate structure includes a top gate located above the second channel member. The source and drain feature is disposed besides the channel members and the gate structure. The source and drain contact is disposed over the source and drain feature. The silicide layer is disposed between the source and drain contact and the source and drain feature. The lining structure is disposed on and in direct contact with the source and drain feature. The lining structure is located between the top gate and the source and drain contact, and a contact surface of the lining structure and the source and drain feature is located above the second channel member

In accordance with some embodiments of the present disclosure, a manufacturing method of a semiconductor device includes forming semiconductor stacks having channel members over a substrate; forming a dummy gate structure wrapping around the semiconductor stacks; forming source and drain features on the substrate and beside the semiconductor stacks and at opposite sides of the dummy gate structure; forming a first dielectric material layer over the substrate and covering top surfaces of the source and drain features; removing the dummy gate structure and forming a gate structure wrapping around the channel members; forming an interlayer over the substrate; performing a first etching process to form first contact openings in the interlayer, wherein the first etching process stops at the first dielectric material layer without etching the source and drain features; forming a second dielectric material layer over the substrate covering the first contact openings; performing a second etching process to etch the first and second dielectric material layers and the source and drain features to form second contact openings extending into the source and drain features, wherein the etched first and second dielectric material layers form a lining structure; forming source and drain contacts in the second contact openings with the lining structure sandwiched between the source and drain contacts and sidewalls of the second contact openings.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
parallel channel members spaced apart and stacked in parallel to the substrate, wherein the parallel channel members comprise an uppermost channel member farthest from the substrate;
a gate structure wrapping around the channel members;
a source and drain feature disposed besides the channel members and the gate structure;
a source and drain contact, disposed on the source and drain feature and besides the gate structure;
a top spacer portion, disposed beside the gate structure, disposed on and in contact with the uppermost channel member; and
a lining structure interposed between the source and drain contact and the top spacer portion,
wherein a bottom of the lining structure is located above the uppermost channel member.

2. The semiconductor device as claimed in claim 1, wherein sidewalls of the top spacer portion are partial covered by the lining structure and sidewalls of the uppermost channel member are not covered by the lining structure.

3. The semiconductor device as claimed in claim 1, wherein sidewalls of the top spacer portion are fully covered by the lining structure and sidewalls of the uppermost channel member are not covered by the lining structure.

4. The semiconductor device as claimed in claim 1, wherein the source and drain feature comprises a first doping concentration area and a second doping concentration area, the first doping concentration area is located between the uppermost channel member and the second doping concentration area, the lining structure is separated from the first doping concentration area.

5. The semiconductor device as claimed in claim 4, wherein a doping concentration of the second doping concentration area is greater than a doping concentration of the first doping concentration area.

6. The semiconductor device as claimed in claim 1, wherein the lining structure includes a composite layer of a first dielectric layer in contact with the source and drain contact and a second dielectric layer in contact with the top spacer portion and the source and drain contact.

7. The semiconductor device as claimed in claim 1, wherein a zone between the uppermost channel member and the source and drain contact is a dielectric-free zone.

8. A semiconductor device, comprising:
channel members spaced apart from one another, wherein the channel members comprise a first channel member and a second channel member disposed above the first channel member;
a gate structure wrapping around the channel members, wherein the gate structure comprises a top gate located above the second channel member;
a source and drain feature disposed besides the channel members and the gate structure;
a source and drain contact disposed over the source and drain feature;
a silicide layer disposed between the source and drain contact and the source and drain feature; and
a lining structure disposed on and in direct contact with the source and drain feature,
wherein the lining structure is located between the top gate and the source and drain contact, and a contact surface of the lining structure and the source and drain feature is located above the second channel member.

9. The semiconductor device as claimed in claim 8, wherein a top end of the silicide layer is located above a top surface of the second channel member.

10. The semiconductor device as claimed in claim 8, wherein the lining structure is in contact with the silicide layer.

11. The semiconductor device as claimed in claim 8, wherein the lining structure comprises a dielectric layer.

12. The semiconductor device as claimed in claim 8, wherein the lining structure comprises a composite layer of a first dielectric material and a second dielectric material stacked on the first dielectric material.

13. The semiconductor device as claimed in claim 8, wherein the source and drain feature comprises a semiconductor zone between the silicide layer and the second channel member.

14. A manufacturing method of a semiconductor device, comprising:
forming semiconductor stacks having channel members over a substrate;
forming a dummy gate structure wrapping around the semiconductor stacks;
forming source and drain features on the substrate and beside the semiconductor stacks and at opposite sides of the dummy gate structure;
forming a first dielectric material layer over the substrate and covering top surfaces of the source and drain features;
removing the dummy gate structure and forming a gate structure wrapping around the channel members;
forming an interlayer over the substrate;
performing a first etching process to form first contact openings in the interlayer, wherein the first etching process stops at the first dielectric material layer without etching the source and drain features;
forming a second dielectric material layer over the substrate covering the first contact openings;
performing a second etching process to etch the first and second dielectric material layers and the source and drain features to form second contact openings extending into the source and drain features, wherein the etched first and second dielectric material layers form a lining structure;
forming source and drain contacts in the second contact openings with the lining structure sandwiched between the source and drain contacts and sidewalls of the second contact openings.

15. The manufacturing method of claim 14, wherein the first dielectric material layer is formed as a single layer.

16. The manufacturing method of claim 14, wherein the first dielectric material layer is formed as a multi-layered structure, and an inner layer of the multi-layered structure has a dielectric constant lower than that of an outer layer of the multi-layered structure.

17. The manufacturing method of claim 14, wherein after the first etching process, the first dielectric material layer is partially removed and the remained first dielectric material layer covers the top surfaces of the source and drain features.

18. The manufacturing method of claim 14, wherein the first contact openings extend into the first dielectric material layer without penetrating through the first dielectric material layer.

19. The manufacturing method of claim 14, wherein after the second etching process, the second contact openings penetrate through the first and second dielectric material layers and extend into the source and drain features.

20. The manufacturing method of claim 14, wherein a bottom of the lining structure is located above an uppermost channel member of the channel members.
